(19) United States
(12) Patent Application Publication
(10) Pub. No.: US 2015/0255535 A1
(43) Pub. Date: Sep. 10, 2015

(54) SEMICONDUCTOR DEVICE AND METHOD FOR MANUFACTURING SAME

(71) Applicant: MITSUBISHI ELECTRIC CORPORATION, Tokyo (JP)

(72) Inventors: Kensuke Taguchi, Tokyo (JP); Tetsuo Takahashi, Tokyo (JP); Atsushi Narazaki, Tokyo (JP)

(73) Assignee: Mitsubishi Electric Corporation, Tokyo (JP)

(21) Appl. No.: 14/433,031

(22) PCT Filed: Jun. 27, 2013
(86) PCT No.: PCT/JP2013/067644

§ 371 Date: Apr. 1, 2015

(30) Foreign Application Priority Data
Oct. 2, 2012 (JP) 2012-219925

(51) Int. Cl. H01L 29/06; H01L 21/266; H01L 21/265; H01L 29/40; H01L 29/739; H01L 29/78; H01L 29/10

(52) U.S. Cl. CPC H01L 29/063; H01L 29/7811; H01L 21/266; H01L 29/0619; H01L 29/0638; H01L 29/1095; H01L 29/402; H01L 29/7395; H01L 21/26513

(57) ABSTRACT

A termination structure located in an outer periphery portion of a semiconductor element includes an N-type drift region formed in a semiconductor substrate and a P-type impurity region formed in an upper surface portion in the N-type drift region. The P-type impurity region has, in macroscopic view, a P-type impurity concentration that decreases from an inner periphery portion toward an outer periphery portion of the termination structure. The P-type impurity region includes, in microscopic view, a plurality of high-concentration regions of the P-type and a low-concentration region surrounding the plurality of high-concentration regions and has a part including the low-concentration regions separate from each other.

### TECHNICAL FIELD

The present invention relates to a semiconductor device and a method for manufacturing the semiconductor device, and more particularly, to the formation of a termination structure provided in the outer periphery portion of a semiconductor element.

### BACKGROUND ART

Power devices, which are semiconductor devices designed for power apparatuses used in, for example, power conversion and power control, have a withstand voltage and a current that are higher than those of common semiconductor devices. Power devices are required to interrupt a current to hold a high voltage in response to application of reverse voltage. As a method for providing the power device having the higher withstand voltage, the technique is known which provides a termination structure, such as a field limiting ring (FLR) structure and a reduced surface field (RESURF) structure, in the outer periphery portion of the semiconductor device.

The FLR structure includes a plurality of P-type impurity regions having a ring shape that surround the main junction between an N-type impurity region having a low concentration and a P-type impurity region formed in the surface portion in the N-type impurity region. For the FLR structure, when a reverse voltage is applied, punch-through occurs sequentially in the junctions formed by the respective P-type impurity regions having a ring shape before occurring in the main junction, so that the electric field in the main junction is relaxed.

The RESURF structure includes a P-type impurity region having a relatively low concentration that is evenly located without being divided. For the RESURF structure, when a reverse voltage is applied, a depletion layer extends from the pn junction to the inside of the P-type impurity region, to thereby hold the voltage. The RESURF structure, which provides a high withstand voltage in a region having a relatively small area, is likely to have an electric field concentration in a particular point. This puts limits on a rise in the withstand voltage of the semiconductor element through relaxation of the electric field concentration.

The structure of the termination region disclosed in the patent documents 1 and 2 described below is the “variation of lateral doping (VLD) structure” in which the impurity concentration distribution of the termination structure in the direction extending from the inner side to the outer side of the semiconductor element is controlled through opening patterns of the implantation mask.

### PRIOR ART DOCUMENTS

### Patent Documents

Patent Document 1: Japanese Patent Application Laid-Open No. 61-084830 (1986)

Patent Document 2: Japanese Patent Application Laid-Open No. 2003-197911

### SUMMARY OF INVENTION

### Problems to be Solved by the Invention

According to the patent document 1, a RESURF layer is formed by ion implantation of impurities through a mask having different aperture ratios in different places and by the subsequent leveling of concentrations through thermal diffusion of impurities. For the thermal diffusion of impurities, this method usually requires a heat treatment at a high temperature for a long period of time. Such a heat treatment at a high temperature for a long period of time results not only in higher manufacturing costs but also in low productivity.

According to the patent document 2, P-type impurity regions are formed by discrete implantation of P-type impurities, and then, the P-type impurities are thermally diffused in a heat treatment, whereby the P-type impurity regions overlap each other. This provides the P-type impurity region in which low-concentration regions formed through the thermal diffusion are located between high-concentration regions. In a case where various concentrations are formed at fixed intervals as in the patent document 2, unfortunately, the reverse withstand voltage is reduced due to manufacturing variations in, for example, the photolithographic process, the ion implantation process, and the etching process for wafer processing.

The present invention has been therefore made to solve the problems described above, and an object thereof is to provide a semiconductor device and a manufacturing method therefor capable of suppressing the occurrence of electric field concentration to obtain a stable reverse withstand voltage while preventing a reduction in productivity.

### Means to Solve the Problems

A semiconductor device according to the present invention includes a semiconductor substrate including a semiconductor element formed therein and a termination structure located in an outer periphery portion of the semiconductor element in the semiconductor substrate. The termination structure includes a first impurity region of a first conductivity type located in the semiconductor substrate and a second impurity region of a second conductivity type located in an upper surface portion in the first impurity region. The second impurity region has, in macroscopic view, a second-conductivity-type impurity concentration that decreases from an inner periphery portion toward an outer periphery portion of the termination structure. In microscopic view, the second impurity region includes a plurality of high-concentration regions of the second conductivity type and a low-concentration region surrounding each of the plurality of high-concentration regions and has a part including second-conductivity-type regions separate from each other.

### Effects of the Invention

The present invention provides a plurality of points that are likely to become high electric fields while extending a depletion layer to the inside of the P-type impurity region, thereby suppressing the electric field concentration and thus providing the semiconductor device having a stable reverse withstand voltage. The second impurity region can be collectively formed by the ion implantation through the implantation mask having an aperture ratio that decreases toward the outer side of the termination structure. The present invention is not intended for leveling of the impurity regions of the second impurity region. This eliminates the need for a thermal treatment at a high temperature for a long period of time and thus prevents a reduction in productivity.

### BRIEF DESCRIPTION OF DRAWINGS

FIG. 1 A plan view showing a configuration of a semiconductor device according to a first embodiment.

FIG. 2 A cross-sectional view showing a configuration of a termination structure of the semiconductor device according to the first embodiment.

FIG. 3 A view showing an example of an implantation mask for forming a P-type impurity region of the termination structure according to the first embodiment.

FIG. 4 A view showing a dose amount distribution in the P-type impurity region of the termination structure according to the first embodiment.

FIG. 5 A view showing an upper-surface structure of the P-type impurity region of the termination structure formed through the implantation mask in FIG. 3.

FIG. 6 A view schematically showing equipotential lines inside a semiconductor substrate of the termination structure according to the first embodiment.

FIG. 7 A view schematically showing equipotential lines inside the semiconductor substrate of the termination structure according to the first embodiment.

FIG. 8 A view schematically showing equipotential lines inside the semiconductor substrate of the termination structure according to the first embodiment.

FIG. 9 A view showing relations between a dose amount of impurities implanted in the termination structure and a reverse withstand voltage in the termination structure.

FIG. 10 A view showing dependence between an impurity concentration and a reverse withstand voltage in the termination structure according to the first embodiment.

FIG. 11 A view schematically showing equipotential lines inside the semiconductor substrate of the termination structure according to the first embodiment.

FIG. 12 A view schematically showing equipotential lines inside the semiconductor substrate of the termination structure according to the first embodiment.

FIG. 13 A view showing a dose amount distribution in the P-type impurity region of the termination structure according to the first embodiment.

FIG. 14 A view showing an upper-surface structure of the P-type impurity region of the termination structure of the semiconductor device according to the first embodiment.

FIG. 15 A view showing an upper-surface structure of the P-type impurity region of the termination structure of the semiconductor device according to the first embodiment.

FIG. 16 An enlarged view of the implantation mask according to the first embodiment.

FIG. 17 A view showing an example of the implantation mask for forming the P-type impurity region of the termination structure according to a second embodiment.

FIG. 18 A view showing a dose amount distribution in the P-type impurity region of the termination structure according to the second embodiment.

FIG. 19 A cross-sectional view showing a configuration of the termination structure of the semiconductor device according to a third embodiment.

FIG. 20 A view showing a dose amount distribution in the P-type impurity region of the termination structure according to the third embodiment.

FIG. 21 A cross-sectional view showing a configuration of the termination structure of the semiconductor device according to a fourth embodiment.

FIG. 22 A cross-sectional view showing a configuration of the termination structure according to the present invention in which a part of an emitter electrode serves as a field plate.

FIG. 23 A cross-sectional view showing a configuration of the termination structure according to the present invention including a channel stopper electrode.

FIG. 24 A cross-sectional view showing a configuration of the termination structure according to the present invention including floating field plates.

FIG. 25 A cross-sectional view showing a configuration of the termination structure of the present invention that is applied to a trench-IGBT-type element structure.

FIG. 26 A cross-sectional view showing a configuration of the termination structure of the present invention that is applied to an element structure including an N-type carrier storage layer.

FIG. 27 A cross-sectional view showing a configuration of the termination structure of the present invention that is applied to an element structure including a diode and an N-type MOSFET.

FIG. 28 A cross-sectional view showing a configuration of the termination structure of the present invention from which a curvature relaxation region is omitted.

### DESCRIPTION OF EMBODIMENTS

The following describes embodiments of the present invention with reference to the drawings. Note that each of the drawings referred to in the description is a simplified view of, for example, a structure of a semiconductor device, and thus, the reduced scale and the aspect ratio thereof are not necessarily accurate.

### First Embodiment

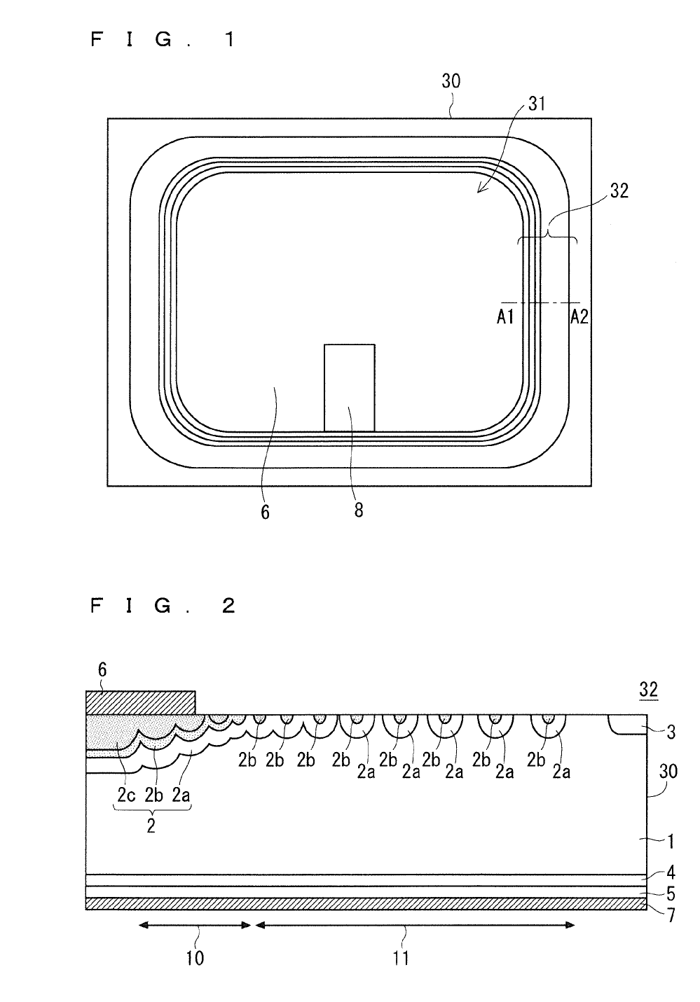

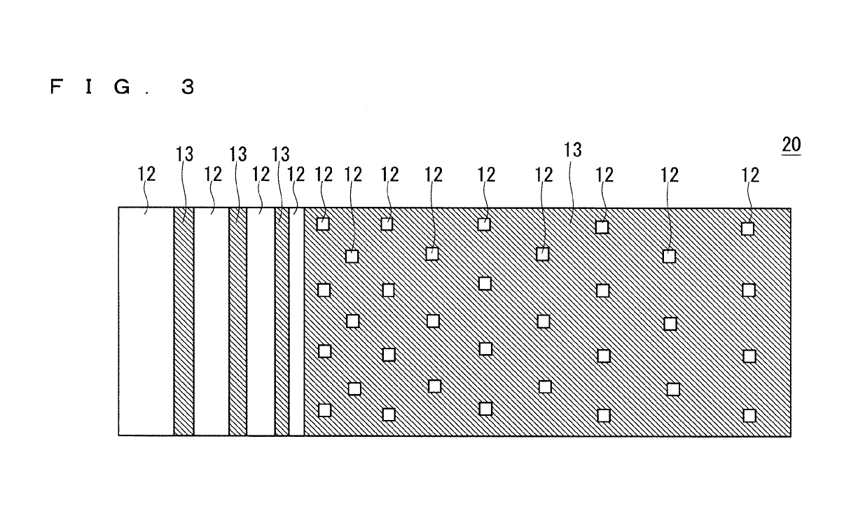

FIGS. 1 and 2 schematically illustrate a configuration of a semiconductor device according to a first embodiment of the present invention. FIG. 1 is a plan view of the semiconductor device and FIG. 2 is a cross-sectional view taken along the line A1-A2 shown in FIG. 1.

The semiconductor device according to the present embodiment includes an insulated gate bipolar transistor (IGBT) 31 that is a semiconductor element formed in a semiconductor substrate 30 made of, for example, silicon (Si) and a termination structure 32 formed in the terminal region in the outer periphery portion of the IGBT 31. FIG. 2 corresponds to the cross sections of the outermost periphery portion of the IGBT 31 and the termination structure 32.

The IGBT 31 includes a gate electrode 8, an emitter electrode 6, an N-type drift region 1, an N-type buffer region 4, a P-type collector region 5, and a collector electrode 7. The gate electrode 8 and the emitter electrode 6 are formed on the upper surface (the main surface) of the semiconductor substrate 30. With reference to FIG. 1, in plan view, the gate electrode 8 is formed in the vicinity of one side of the semiconductor substrate 30 and the emitter electrode 6 is formed to cover the entirety of the IGBT 31 except the formation region of the gate electrode 8.

The N-type drift region 1, the N-type buffer region 4, and the P-type collector region 5 are impurity regions formed inside the semiconductor substrate 30. The N-type drift region 1 is formed throughout the inside of the semiconductor substrate 30. The N-type buffer region 4 is formed below the N-type drift region 1. The P-type collector region 5 is formed below the N-type buffer region 4. The collector electrode 7 connected to the P-type collector region 5 is formed on the lower surface of the semiconductor substrate 30.

With reference to FIG. 2, the termination structure 32 includes the N-type drift region 1 (first impurity region) formed in the semiconductor substrate 30, a P-type impurity region 2 (second impurity region) and an N-type channel stopper region 3 formed in the upper surface portion in the N-type drift region 1. The P-type impurity region 2 in the inner periphery portion of the termination structure 32 is connected to the P-type impurity region (p well) in the outermost periphery of the IGBT 31.

As shown in FIG. 2, the P-type impurity region 2 is divided into three regions being regions 2a, 2b, and 2c according to the P-type impurity concentrations. The region 2c has the highest impurity concentration, the region 2b has the second-highest impurity concentration, and the region 2a has the lowest impurity concentration. The region 2a is hereinafter referred to as a “low-concentration region” and the regions 2b and 2c are hereinafter referred to as “high-concentration regions.”

The impurity concentration of the low-concentration region 2a is set at a value that satisfies the condition (RESURF condition) for transforming the low-concentration region 2a into the complete depletion state. The impurity concentration of the high-concentration region 2c is set at a value that satisfies the condition for leaving the high-concentration region 2c in the state that is substantially free from depletion. The impurity concentration of the high-concentration region 2b is set at a value just enough to allow the transformation of the high-concentration region 2b into the depletion state to depend on variations in the wafer processing.

The high-concentration region 2c is formed by ion implantation of P-type impurities. Meanwhile, the high-concentration regions 2b and the low-concentration regions 2a are formed by thermally diffusing impurities mainly from the high-concentration regions 2c. Consequently, the high-concentration regions 2b and the low-concentration regions 2a are formed to surround the high-concentration region 2c. That is, the high-concentration regions 2b are located in the upper surface portion in the low-concentration regions 2a and the high-concentration region 2c is located in the upper surface portion in the high-concentration regions 2b.

The high-concentration regions 2b including no high-concentration region 2c inside thereof are shown in the termination structure 32 in FIG. 2. Such high-concentration regions 2b result from the thermal diffusion occurring throughout the high-concentration regions 2c having a small dimension that are formed in the regions in which the implantation mask used in the ion implantation has a low aperture ratio (openings with a small dimension). Alternatively, the high-concentration regions 2b having an impurity concentration lower than that of the high-concentration region 2c may be formed in a case where the dose amount of implanted impurities is reduced because the openings of the implantation mask have a small dimension.

The P-type impurity region (p well) in the outermost periphery of the IGBT 31 that is connected to the inner periphery portion of the P-type impurity region 2 has an impurity concentration higher than that of the P-type impurity region 2 and is formed to be deeper than the P-type impurity region 2. As shown in FIG. 2, the P-type impurity region 2 in the inner periphery portion of the termination structure 32 is formed to gradually become deeper toward the P-type impurity region in the outermost periphery of the IGBT 31. In addition, the impurity concentration gradually increases toward the P-type impurity region in the outermost periphery of the IGBT 31. Consequently, the curvature of the lower end portion of the P-type impurity region in the outermost periphery of the IGBT 31 is relaxed, which prevents the electric field concentration in such portion. The inner periphery portion of the termination structure 32 is referred to as a “curvature relaxation region 10.”

In the region outside of the curvature relaxation region 10, the high-concentration regions 2b are formed to be separate from each other. The gap between the high-concentration regions 2b increases as closer to the outer periphery portion of the termination structure 32 and the low-concentration regions 2a are separate from each other in the vicinity of the outer periphery portion of the termination structure 32. Thus, as viewed macroscopically, the impurity concentration of the P-type impurity region 2 of the termination structure 32 decreases toward the outer side of the termination structure 32. As viewed microscopically, the P-type impurity region 2 includes a plurality of the high-concentration regions 2b and low-concentration regions 2a therearound and the low-concentration regions 2a and the high-concentration regions 2b are arranged alternately. Such region, which holds the reverse withstand voltage of the semiconductor substrate 30, is referred to as a “withstand voltage holding region 11.”

The N-type channel stopper region 3 is formed in the outer periphery portion of the termination structure 32 (corresponding to the end portion of a semiconductor chip). Although the N-type channel stopper region 3 is formed to be separate from the P-type impurity region 2 in the present embodiment, the N-type channel stopper region 3 may be in contact with the low-concentration region 2a in the outermost periphery. The N-type channel stopper region 3 has an N-type impurity concentration higher than that of the N-type drift region 1.

FIG. 3 illustrates an example of an implantation mask 20 used in the ion implantation for forming the P-type impurity region 2. In the present embodiment, the implantation mask 20 is formed of a silicon oxide film 13 having openings 12. The openings 12 in the implantation mask 20 have, for example, a line-shaped pattern or a dot-shaped pattern.

The implantation mask 20 has a pattern in which, as viewed macroscopically, the aperture ratio of the implantation mask 20 (the proportion of the area of the openings 12) decreases from the inner side to the outer side of the termination structure 32 (in the width direction of the termination structure 32). In a case where the implantation mask 20 is formed over the semiconductor substrate 30 and the region in which the implantation mask 20 has the aperture ratio of 1% is subjected to the ion implantation of impurities with the dose amount of 1E+14 cm⁻² and to the thermal diffusion of the impurities, the dose amount of the impurities implanted in the region is 1E+12 cm⁻², which is equivalent to 1% of 1E+14 cm⁻², in macroscopic view.

The P-type impurity region 2 is formed through: the formation of the high-concentration region 2c in the semiconductor substrate 30 by ion implantation of P-type impurities using the implantation mask 20; and the subsequent formation of the high-concentration regions 2b and low-concentration regions 2a by thermal diffusion of the P-type impurities in a heat treatment.

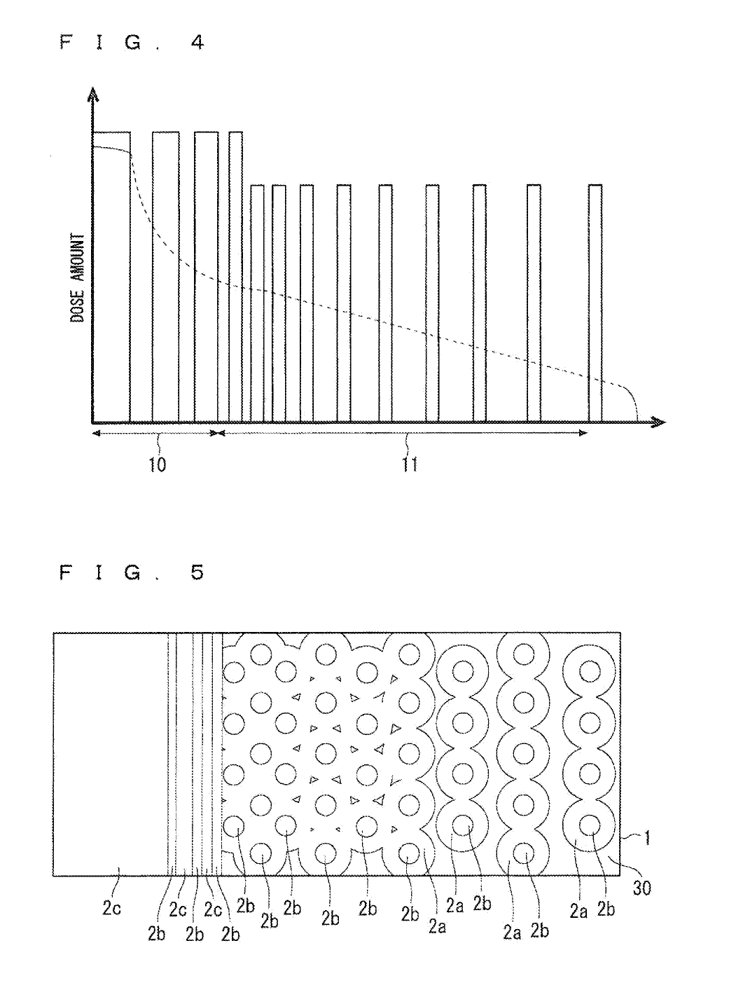

FIG. 4 shows a dose amount distribution of the impurities in the P-type impurity region 2 as a result of the ion implantation for forming the P-type impurity region 2 of the termination structure 32 through the use of the implantation mask 20 shown in FIG. 3. The solid lines indicate the dose amount in microscopic view and the dashed line indicates the dose amount in macroscopic view. As shown in FIG. 4, the dose amount in macroscopic view gradually decreases toward the outer side of the termination structure 32.

In the present embodiment, the distribution of the aperture ratios of the implantation mask 20 is controlled, which allows the dose amount in macroscopic view to be inclined without any increase in the number of steps in the wafer processing, so that the P-type impurity region 2 in the curvature relaxation region 10 having a relatively high concentration and the P-type impurity region 2 in the withstand voltage holding region 11 having a relatively low concentration can be collectively formed in a single ion-implantation process.

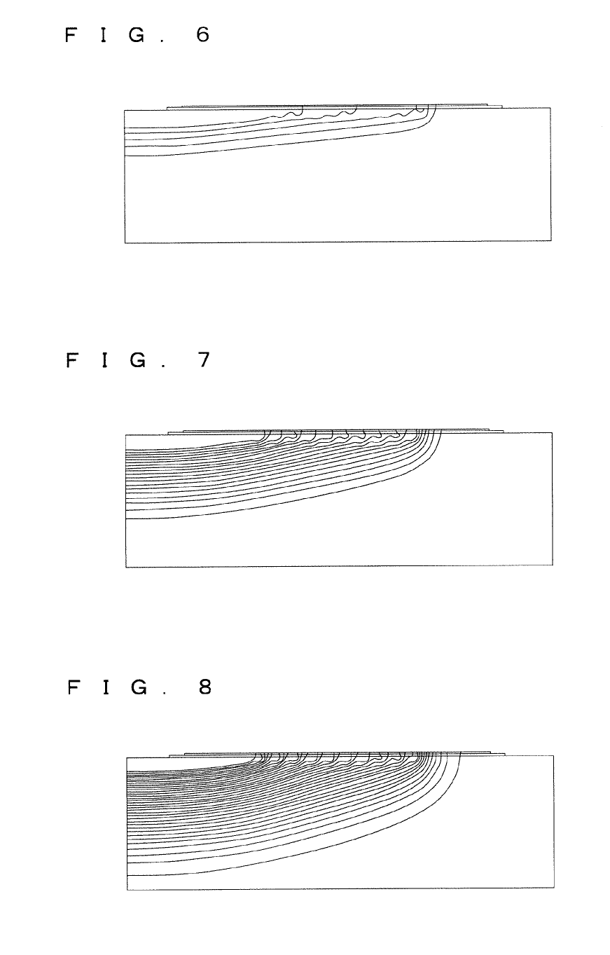

The P-type impurity region 2 in the curvature relaxation region 10 is formed through: the formation of the high-concentration region 2c immediately below the openings 12 by ion implantation in the region of the implantation mask 20 having the openings 12 that are line-shaped (or the region in which the openings 12 that are window-shaped are arranged in high density); and the subsequent formation of the high-concentration region 2b and the low-concentration region 2a around the high-concentration region 2c by a heat treatment. The P-type impurity region 2 in the withstand voltage holding region 11 is formed through the formation of the high-concentration regions 2b immediately below the openings 12 and the formation of the low-concentration regions 2a around the high-concentration regions 2b by the ion implantation and the heat treatment described above in the region of the implantation mask 20 having the openings 12 located separate from each other. In a case where the implantation mask 20 shown in FIG. 3 is used, the upper surface of the P-type impurity region 2 after the diffusion of the P-type impurities by the heat treatment has the structure shown in FIG. 5.

For the semiconductor device including the termination structure 32 shown in FIG. 2, in response to application of the reverse voltage that causes the electric potential of the collector electrode 7 to be higher than the electric potential of the emitter electrode 6, the voltage is applied to the junction portion between the N-type drift region 1 and the low-concentration regions 2a of the P-type impurity region 2 (for the case that the N-type channel stopper region 3 and the low-concentration region 2a are joined to each other, the junction portion therebetween) in the upper surface portion of the termination structure 32, so that a depletion layer extends from the N-type-channel-stopper-region-3 side (the high-voltage side) to the low-concentration-regions-2a side (the low-voltage side).

The depletion layer extending from the boundary between the lower part of the low-concentration regions 2a and the N-type drift region 1 toward the surface of the semiconductor substrate 30 transforms the low-concentration regions 2a into the complete depletion state. At this time, if the impurity concentration of the low-concentration regions 2a is properly set, the depletion state extends to the surface and the inside of the low-concentration regions 2b or to the upper surface of the semiconductor substrate 30 before the electric field of the above-described junction portion exceeds the critical point to result in breakdown.

Along with the further increase in the electric potential of the collector electrode 7, the depletion layer extends inside the high-concentration regions 2b. At this time, if the impurity concentration and the positional relation of the high-concentration regions 2b are properly set, the depletion state extends to the vicinity of the upper surfaces of the high-concentration regions 2b or to the upper surface of the semiconductor substrate 30 before the electric field of the above-described junction portion exceeds the critical point to result in breakdown. Consequently, each of the high-concentration regions 2b has a point that is likely to become a high electric field, whereby the maximum electric field intensity of each point is suppressed to provide the stable reverse withstand voltage.

Thus, the reverse withstand voltage is held by the depletion layer that is formed inside the low concentration regions 2a and the high-concentration regions 2b and inside the N-type drift region 1.

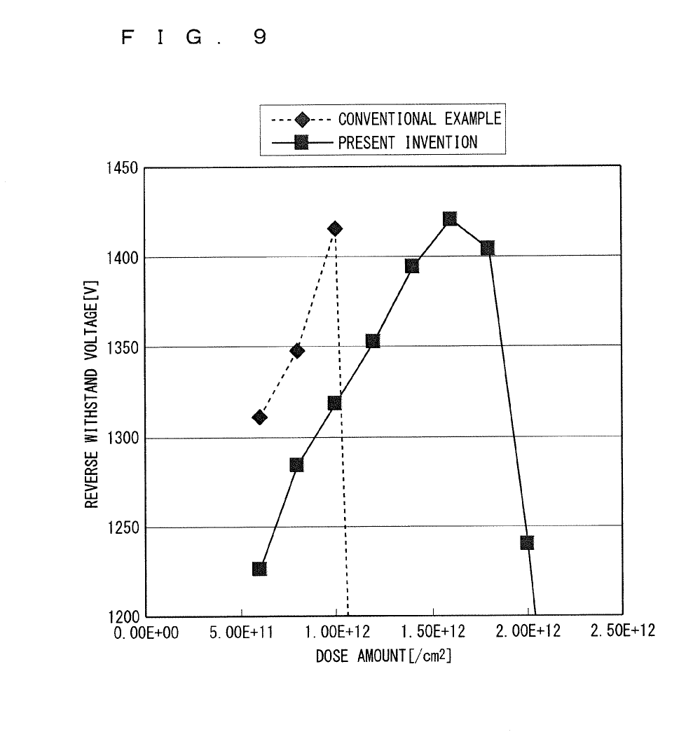

FIGS. 6 to 8 illustrate equipotential lines inside the semiconductor 30 of the termination structure 32 shown in FIG. 2. FIGS. 6, 7, and 8 show the reverse withstand voltage that increases in the stated order. As shown in the drawings, the gaps between the equipotential lines are substantially even, which indicates the suppression of the electric field concentration in particular points of the termination structure 32.

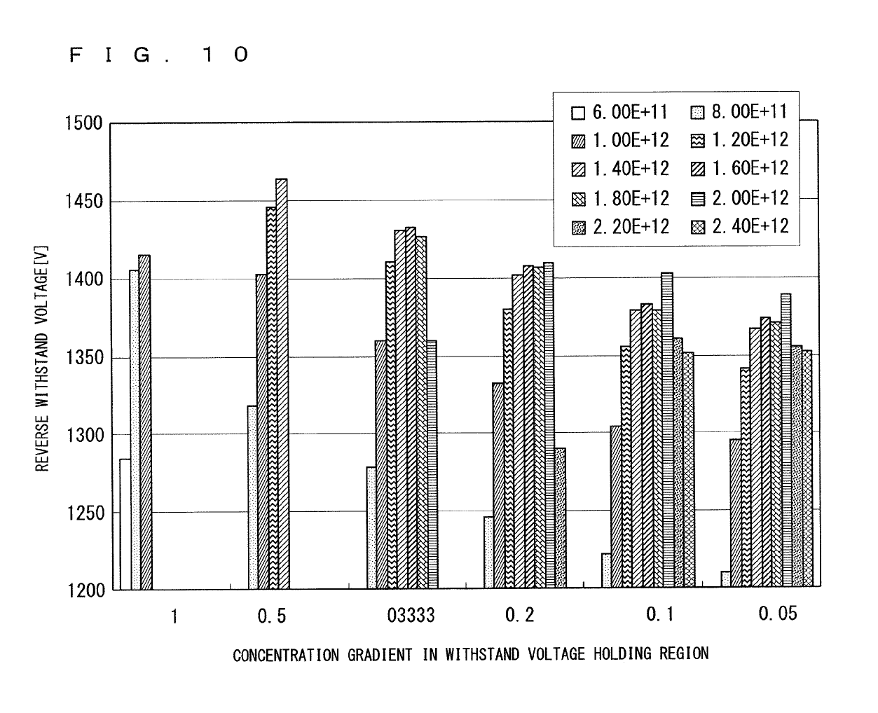

FIG. 9 shows relations between the dose amount of impurities implanted in the termination structure and the reverse withstand voltage in the termination structure. In FIG. 9, the solid line indicates the relations in the termination structure according to the present embodiment and the dashed line indicates the relations in the conventional termination structure (the structure in which the P-type impurity region in the withstand voltage holding region has the uniform impurity concentration).

As for the conventional termination structure, when the P-type impurity region of the termination structure is implanted with impurities in high concentrations, a high electric field is generated in the P-type impurity region of the outermost periphery, causing a decline in withstand voltage. As for the termination structure according to the present invention, meanwhile, even if the P-type impurity region of the termination structure is implanted with impurities in high concentrations, the P-type impurity region of the outer periphery portion has a low impurity concentration in macroscopic view. This suppresses the generation of high electric field in the P-type impurity region of the outermost periphery. Thus, the area having the impurity concentration (the dose amount) that provides a high reverse withstand voltage is more extensive in the termination structure according to the present invention than in the conventional termination structure, whereby a stable withstand voltage can be provided despite variations in the wafer processing.

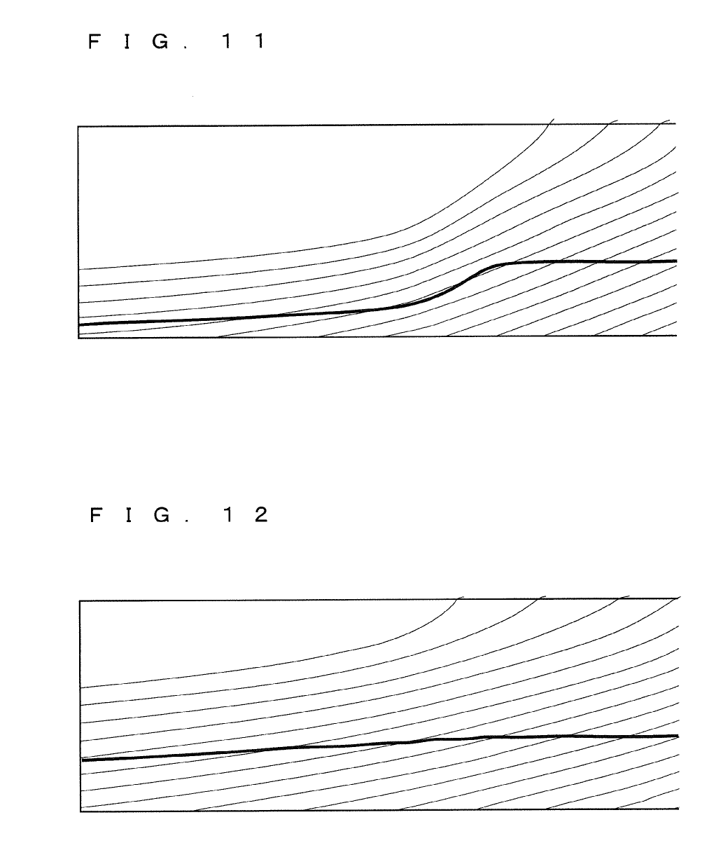

The impurity concentration (the dose amount) and the reverse withstand voltage in the P-type impurity region are dependent on each other. FIG. 10 shows the dependency. With reference to FIG. 10, the impurity implantation amount in the N-type drift region 1 of the semiconductor substrate 30 is set at 8.85 E+13 cm⁻² and the dose amount of the P-type impurities implanted in the wafer processing is set at 3.0 E+14 cm⁻². The dose amount shown in FIG. 10 indicates the dose amount for the case that the innermost periphery portion of the withstand voltage holding region 11 is viewed macroscopically.

FIG. 10 indicates that the stable reverse withstand voltage is provided when the dose amount in the innermost periphery of the withstand voltage holding region 11 in macroscopic view is 1.0 E+12 cm⁻² to 2.0 E+12 cm⁻² and the dose amount in the withstand voltage holding region 11 in macroscopic view has a gradient of ⅓ to 1/20 (0.3333 to 0.05) toward the outer side.

Alternatively, as indicated in FIG. 10, the semiconductor device allowing for the stable reverse voltage is provided when the dose amount in the innermost periphery of the withstand voltage holding region 11 in macroscopic view is 1.0 E+12 cm⁻² to 1.4 E+12 cm⁻² and the dose amount in the withstand voltage holding region 11 in macroscopic view has a gradient of ½ (0.05) toward the outer side.

The P-type impurity region 2 of the withstand voltage holding region 11 is formed to have such an impurity concentration profile by decreasing, toward the outer side of the termination structure 32, the aperture ratio of the implantation mask 20 (in, for example, FIG. 3) used in the ion implantation for forming the P-type impurity region 2.

As an example of decreasing rate of aperture ratio of the implantation mask 20, the aperture ratio may be reduced to about 1/50 from the inner periphery portion to the outer periphery portion of the curvature relaxation region 10. In addition, in the outer periphery portion of the withstand voltage holding region 11, the aperture ratio is reduced to the point where the impurity concentration in macroscopic view is low enough so that P-type impurity region 2 is transformed into the depletion state. Besides the functions including a linear function for reducing the aperture ratio, the function providing a higher reduction rate, such as an exponential function, is desirable. For example, in macroscopic view, the use of an exponential function that is convex downward or a function that decreases according to the polynomial expression successfully relaxes the local concentration of electric field.

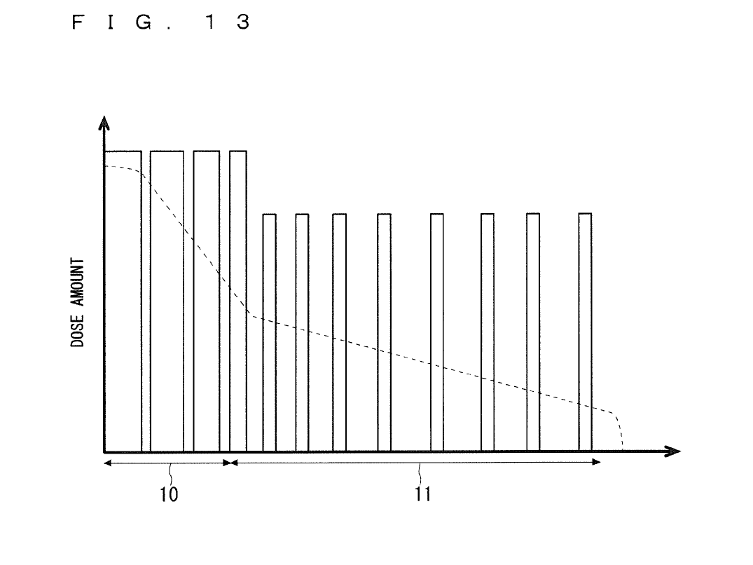

FIGS. 11 and 12 schematically illustrate equipotential lines inside the semiconductor substrate 30 of the termination structure 32. The thin lines in FIGS. 11 and 12 indicate the equipotential lines and the thick lines indicate pn junctions.

FIG. 11 shows the case in which the impurity concentration profile of the curvature relaxation region 10 has the concentration linearly decreasing from the inner periphery toward the outer periphery of the semiconductor device in macroscopic view as in FIG. 13. FIG. 12 shows the case in which the impurity concentration profile of the curvature relaxation region 10 decreases from the inner periphery portion to the outer periphery portion to provide the downward-convex function in macroscopic view as in FIG. 4. FIG. 11 shows that the gaps between the equipotential lines are narrowed locally. Meanwhile, FIG. 12 shows that the gaps between the equipotential lines are substantially even. That is, the electric field concentration in particular points of the termination structure 32 is further suppressed in FIG. 12.

Reducing the concentration continuously from the inner periphery portion to the outer periphery portion of the termination structure 32 in microscopic view is, in some cases, difficult due to limitations on the wafer processing, but the present invention does not necessarily require the continuous reduction in concentration in microscopic view. As shown in FIG. 4, for example, the similar effects can be provided if the amount of change in impurity concentration in macroscopic view gradually decreases from the inner periphery portion to the outer periphery portion of the curvature relaxation region 10 (in other words, gradually increases toward the high-concentration region 2c).

For the reduction in aperture ratio of the implantation mask 20 in accordance with a linear function, in a case where the silicon oxide film 13 is formed such that the aperture ratio at a position x, which is located along the direction from the inner periphery portion to the outer periphery portion of the withstand voltage holding region 11, is 100× 1/50×(−ax+b) %, the effective dose amount at x=(b−1/5.0)/a decreases to about one-fifth of the dose amount for the case that the aperture ratio is 2%. If this is the case, the appropriate selection of the dose amount, the dimension of the withstand voltage holding region 11, and the values of a and b provides the P-type impurity region 2 with the desired impurity concentration profile.

The implantation mask 20 has, for example, the pattern in which the openings 12 that are dot-shaped (hereinafter referred to as “implantation windows”) have a fixed dimension and the gap between the implantation windows increases toward the outer side of the termination structure 32. For example, each of the implantation windows of the implantation mask 20 has the dimension of 0.4 μm. Each of the gaps between the implantation windows in the circumferential direction of the termination structure 32 is 2.8 μm. Each of the gaps between the implantation windows in the width direction of the termination structure 32 is 2.8 μm in the innermost periphery portion of the withstand voltage holding region 11 and is extended to 14.0 μm in the outermost periphery portion thereof.

Compared to the P-type impurity region 2 that is integrally formed to be continuous through the entirety thereof in the withstand voltage holding region 11, the P-type impurity region 2 that is partially unconnected as shown in FIG. 2 can provide the reverse withstand voltage with increased stability.

For the P-type impurity region 2 that is continuous through the entirety thereof, when the dose amount of implanted P-type impurities has a high concentration because of variations in the wafer processing, the regions having the P-type impurity concentration (the highest concentration capable of producing the complete depletion state) that is appropriate for the reverse withstand voltage holding are substantially eliminated. Consequently, the region in depletion state for holding the reverse withstand voltage is narrowed, which causes electric field concentration in the outermost periphery portion of the P-type impurity region 2 and thus lowers the withstand voltage.

As for the P-type impurity region 2 having unconnected parts formed therein in the withstand voltage holding region 11, even if the dose amount of implanted P-type impurities has a high concentration because of variations in the wafer processing, the reverse withstand voltage is improved due to formation of a number of regions having the P-type impurity concentration that is appropriate for holding the reverse withstand voltage in the width direction of the termination structure 32. Thus, in the present embodiment, the gaps between the openings 12 of the implantation mask 20 are set so as to allow some of the adjacent low-concentration regions 2a to be connected and others to be unconnected during the heat treatment for the formation of the low-concentration region 2a through thermal diffusion.

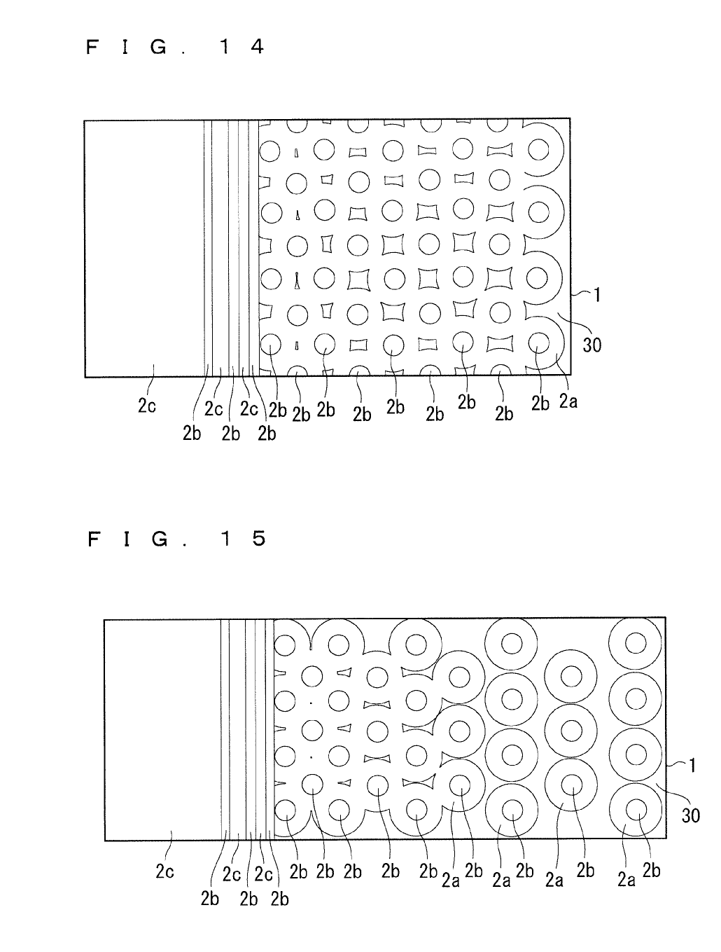

Although FIGS. 2 and 5 show an example of the P-type impurity region 2 having unconnected parts in the width direction of the termination structure 32, the P-type impurity region 2 having unconnected parts only in the circumferential direction of the termination structure 32 as shown in FIG. 14 produces the similar effects. This is because the P-type impurity region 2 having unconnected parts in the circumferential direction of the termination structure 32 allows the P-type impurities to diffuse in the circumferential direction in the heat treatment, thereby providing the P-type impurity concentration that is appropriate for holding the withstand voltage.

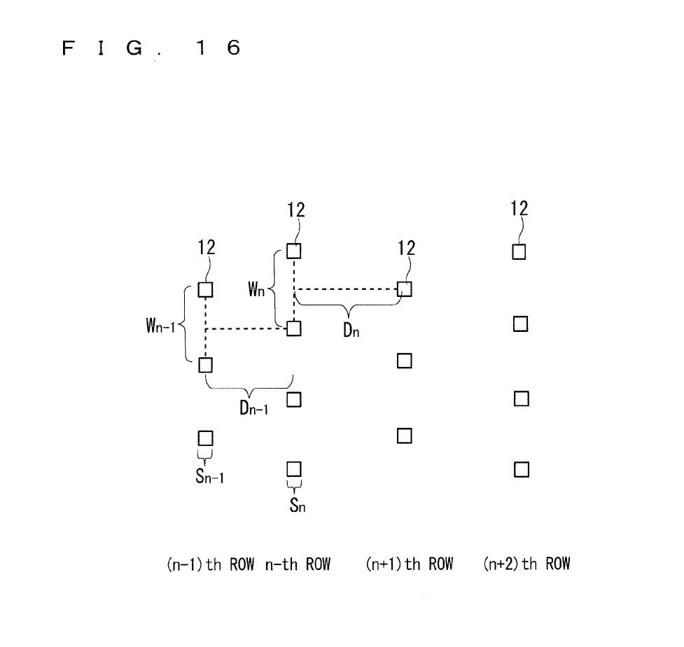

In addition, the structure in which the P-type impurity region 2 has unconnected parts both in the width direction and the circumferential direction of the termination structure 32 as shown in FIG. 15 (the structure including the insular arrangement of the P-type impurity region 2) produces the similar effects, further increasing the margin for the wafer processing. In particular, the use of the semiconductor substrate 30 including the N-type drift region 1 in low impurity concentrations requires fine adjustments to provide the optimum impurity concentration in the P-type impurity region 2. The increased margin for the wafer processing facilitates such adjustment to provide the stable reverse withstand voltage.

Note that, the excessively-wide gaps between the implantation windows in the circumferential direction of the termination structure 32 cause the regions having low P-type impurity concentrations to extend in the width direction of the termination structure 32. This provides the stable reverse withstand voltage but is unfavorable in terms of reduction in the absolute value of the reverse withstand voltage. Thus, the gaps between the implantation windows need to be set appropriately.

The implantation mask 20 may have any given pattern and the implantation mask 20 with any pattern produces a certain effect. The following describes, in particular, the arrangement example of the implantation windows with reference to FIG. 16.

FIG. 16 is an enlarged view of the implantation mask 20 for forming the P-type impurity region 2 in the withstand voltage holding region 11. In FIG. 16, Sₙ represents the dimension of the implantation window (the opening 12) in the n-th row from the inner periphery side, Dₙ represents the gap between the implantation window in the n-th row and the implantation window in the (n+1)th row in the width direction of the termination structure 32, and Wₙ represents the gap between the implantation windows in the n-th row in the circumferential direction of the termination structure 32.

For example, the dimension (Sₙ) of the implantation windows is fixed, the gap (Dₙ) between the implantation windows in the width direction of the termination structure 32 increases continuously or in stages toward the outer side, and the gap (Wₙ) between the implantation windows in the circumferential direction of the termination structure 32 is fixed. Consequently, the impurity concentration (the dose amount) in the P-type impurity region 2 in macroscopic view gradually decreases from the inner periphery portion toward the outer periphery portion of the termination structure 32.

As another example, the dimension (Sₙ) of the implantation windows is fixed, the gap (Dₙ) between the implantation windows in the width direction of the termination structure 32 is fixed, and the gap (Wₙ) between the implantation windows in the circumferential direction of the termination structure 32 increases continuously or in stages toward the outer side. This also provides the impurity concentration distribution similar to that of the above in macroscopic view.

The same holds true for the case in which the dimension (Sₙ) of the implantation windows is fixed, the gap (Dₙ) between the implantation windows in the width direction of the termination structure 32 increases continuously or in stages toward the outer side, and the gap (Wₙ) between the implantation windows in the circumferential direction of the termination structure 32 increases continuously or in stages toward the outer side.

As still another example, the implantation windows in the (n+1)th row adjacent to the n-th row deviate by Wₙ/2 in the circumferential direction of the termination structure 32 from the implantation windows in the n-th row. Each row may have the same deviation, thereby providing the implantation windows arranged in a zigzag pattern as shown in FIG. 16. In this arrangement, variations in the impurity concentrations of the P-type impurity region 2 can be evenly formed in the withstand voltage holding region 11, resulting in the two-dimensional decentralization of the part having high electric field intensity. Consequently, the maximum electric field intensity in the withstand voltage holding region 11 is further reduced, thereby providing the reverse withstand voltage with increased stability.

The implantation mask 20, which is formed of the silicon oxide film 13 according to the example described above, may be formed of materials, such a resist pattern, used as the implantation mask in the common semiconductor processing.

The implantation windows (the openings 12 that are dot-shaped) provided in the implantation mask 20 may have any given shape, such as a circle, a rectangle, and an ellipse besides a square as described above, providing the similar effects. In particular, if the openings have a rectangular shape, the implantation mask 20 is desirably arranged such that the long sides of the openings extend along the circumferential direction of the termination structure 32. Although the implantation mask 20 shown in FIG. 3 includes insulating films 21 that are line-shaped and provided in the inner periphery portion of the termination structure 32 and has the openings 12 that are dot-shaped and provided outside of the insulating films 21, the implantation mask 20 is not required to have both the openings 12 that are line-shaped and the openings 12 that are dot-shaped, and thus, may include one of the openings 12 that are line-shaped and the openings 12 that are dot-shaped.

Although the P-type impurity region 2 according to the first embodiment includes the low-concentration region 2a, the high-concentration region 2b, and the high-concentration region 2c that differ in impurity concentration (dose amount), the P-type impurity region 2 may have the uniform concentration in microscopic view as long as the impurity concentration in macroscopic view gradually decreases toward the outer side of the termination structure 32. For example, in the P-type impurity region 2 having the uniform concentration in microscopic view, the P-type regions that are separate from each other are provided to increase in number (or in area) toward the outer side of the termination structure 32, so that the impurity concentration in macroscopic view gradually decreases toward the outer side of the termination structure 32. Similarly to the first embodiment, this example provides the stable reverse withstand voltage despite variations in the wafer processing. The same holds true for the embodiments described below.

### Second Embodiment

As shown in FIG. 4, the impurity concentration of the P-type impurity region 2 in the withstand voltage holding region 11 of the termination structure 32 decreases, in macroscopic view, toward the outer side in accordance with the linear function, which may be replaced by an upward-convex function or a downward-convex function as long as the impurity concentration decreases monotonously in macroscopic view.

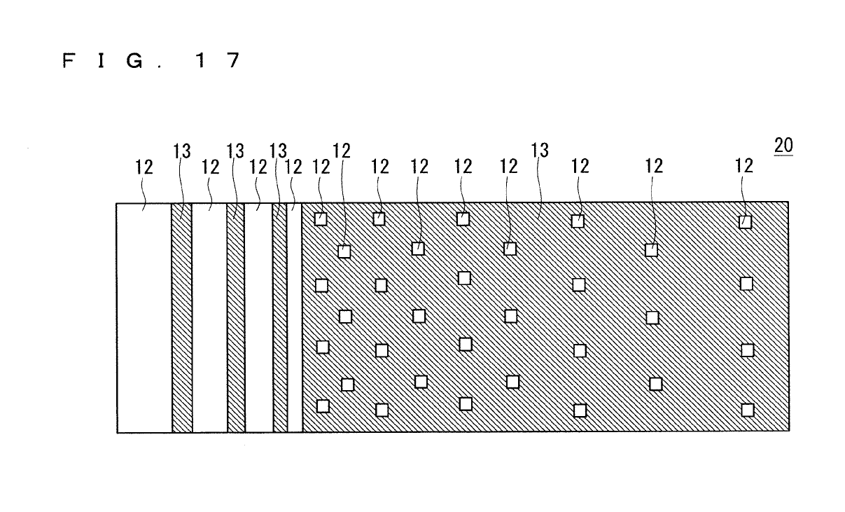

FIG. 17 illustrates the implantation mask for forming the P-type impurity region of the termination structure according to a second embodiment. Compared with the example in FIG. 3, the implantation mask 20 in FIG. 17 has an increased aperture ratio (density of the openings 12) in the vicinity of the inner periphery of the withstand voltage holding region 11 and a decreased aperture ratio in the vicinity of the outer periphery thereof.

The dose amount distribution in the P-type impurity region 2 that is formed through the implantation mask 20 in FIG. 17 is as shown in FIG. 18. The solid lines indicate the dose amount in microscopic view and the dashed line indicates the dose amount in macroscopic view. As shown in FIG. 18, the dose amount in macroscopic view decreases toward the outer side of the termination structure 32 in accordance with the upward-convex function. That is, the amount of change in the dose amount in macroscopic view gradually increases toward the outer side of the termination structure 32.

As viewed macroscopically, in a case where the impurity concentration (the dose amount) in the withstand voltage holding region 11 decreases continuously or in stages toward the outer side of the termination structure 32 in accordance with a convex function, a region having a further reduced concentration in macroscopic view is formed in the outermost periphery of the P-type impurity region 2 compared with the case in which the concentration decreases linearly. Consequently, the reverse withstand voltage can be naturally held at the appropriate dose amount, and furthermore, the electric field concentration in the outermost periphery of the P-type impurity region 2 can be suppressed even if the concentration of the dose amount of implanted P-type impurities increases due to variations in the wafer processing.

Examples of such convex function include a quadratic function and a progression, such as Xₙ+1=αXₙ+β (α and β are arbitrarily given). To obtain the impurity concentration given by a convex function in macroscopic view in the P-type impurity region 2 of the termination structure 32, the openings 12 are arranged such that the aperture ratio of the implantation mask 20 is in accordance with a convex function toward the outer side of the termination structure 32.

### Third Embodiment

Although the implantation windows (the openings 12) provided in the implantation mask 20 have a fixed dimension in the first and second embodiments, the dimensions of the implantation windows may be controlled, which can also change the impurity concentration in the P-type impurity region 2 in macroscopic view.

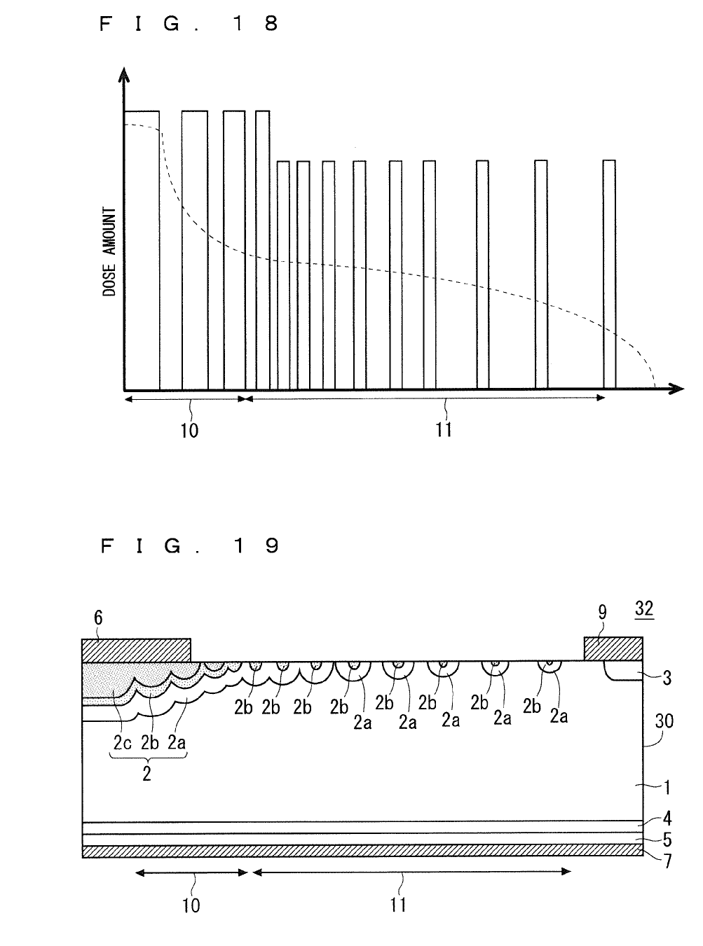

FIG. 19 is a cross-sectional view showing a configuration of the termination structure of the semiconductor device according to a third embodiment. According to the present embodiment, the P-type impurity region 2 of the termination structure 32 is formed through the implantation mask 20 in which the dimensions of the implantation windows decrease from the inner side toward the outer side of the withstand voltage holding region 11.

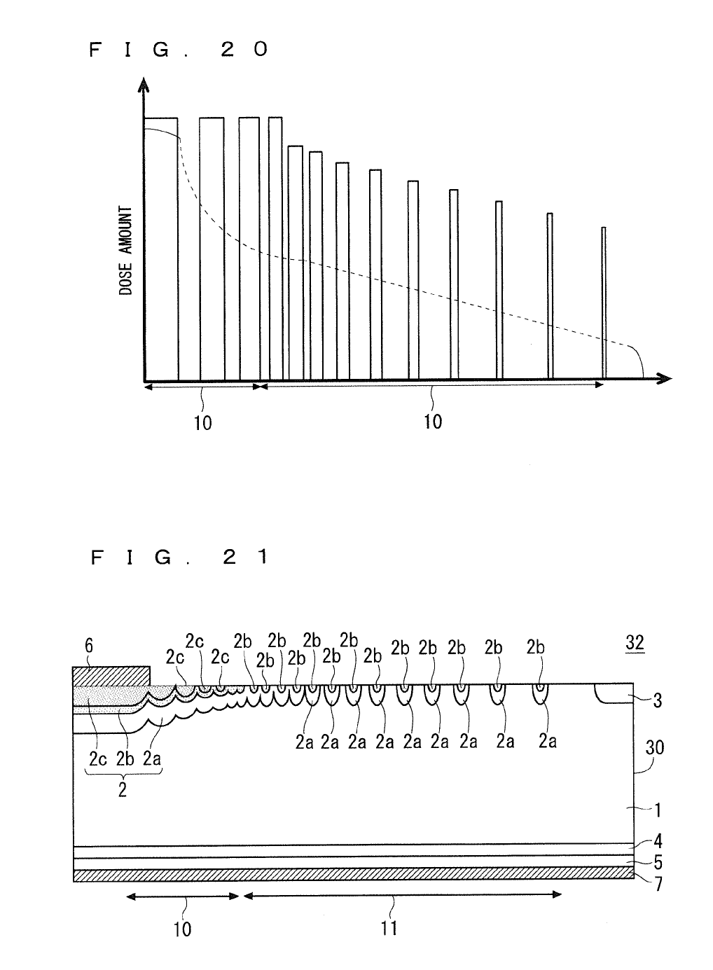

FIG. 20 shows the dose amount distribution in the P-type impurity region 2 of the termination structure 32 in the above case. The solid lines indicate the dose amount in microscopic view and the dashed line indicates the dose amount in macroscopic view. The present embodiment also has the dose amount in macroscopic view that gradually decreases toward the outer side of the termination structure 32. As viewed microscopically, the regions having a large dose amount and the regions having a small dose amount are arranged alternately. This arrangement provides the stable reverse withstand voltage despite variations in the wafer processing as in the first embodiment.

The implantation mask 20 may have any given pattern and the implantation mask 20 with any pattern produces a certain effect. The following describes, in particular, the arrangement example of the implantation windows with reference to FIG. 16.

For example, dimension (Sₙ) of the implantation windows is fixed, the gap (Dₙ) between the implantation windows in the width direction of the termination structure 32 is fixed, and the gap (Wₙ) between the implantation windows in the circumferential direction of the termination structure 32 decreases continuously or in stages toward the outer side. This provides the impurity concentration distribution similar to the above in macroscopic view.

As another example, the dimension (Sₙ) of the implantation windows decreases in stages or continuously from the inner side toward the outer side of the termination structure 32, the gap (Dₙ) between the implantation windows in the width direction of the termination structure 32 is fixed, and the gap (Wₙ) between the implantation windows in the circumferential direction of the termination structure 32 is fixed. Consequently, the impurity concentration (the dose amount) in the P-type impurity region 2 in macroscopic view gradually decreases from the inner periphery portion toward the outer periphery portion of the termination structure 32.

As another example, the dimension (Sₙ) of the implantation windows decreases in stages or continuously from the inner side toward the outer side of the termination structure 32, the gap (Dₙ) between the implantation windows in the width direction of the termination structure 32 increases continuously or in stages toward the outer side, and the gap (Wₙ) between the implantation windows in the circumferential direction of the termination structure 32 is fixed. This provides the impurity concentration distribution similar to the above in macroscopic view.

In another case, the dimension (Sₙ) of the implantation windows decreases in stages or continuously from the inner side toward the outer side of the termination structure 32, the gap (Dₙ) between the implantation windows in the width direction of the termination structure 32 is fixed, and the gap (Wₙ) between the implantation windows in the circumferential direction of the termination structure 32 increases continuously or in stages toward the outer side. This provides the impurity concentration distribution similar to the above in macroscopic view.

The same holds true for the case in which the dimension (Sₙ) of the implantation windows decreases in stages or continuously from the inner side toward the outer side of the termination structure 32, the gap (Dₙ) between the implantation windows in the width direction of the termination structure 32 increases continuously or in stages toward the outer side, and the gap (Wₙ) between the implantation windows in the circumferential direction of the termination structure 32 increases continuously or in stages toward the outer side.

In still another case, the implantation windows in the (n+1)th row adjacent to the n-th row may deviate by Wₙ/2 in the circumferential direction of the termination structure 32 from the implantation windows in the n-th row, providing the implantation windows arranged in a zigzag pattern as shown in FIG. 16. In this arrangement, variations in the impurity concentrations of the P-type impurity region 2 can be evenly formed in the withstand voltage holding region 11, resulting in the two-dimensional decentralization of the part having high electric field intensity. Consequently, the maximum electric field intensity in the withstand voltage holding region 11 is further reduced, thereby providing the reverse withstand voltage with increased stability.

The dimensions of the implantation windows and the P-type impurity concentration in the surface of the semiconductor substrate 30 after the ion implantation and the thermal diffusion are dependent on each other. The implantation windows are formed to have the dimensions that decrease toward the outer side of the termination structure 32, allowing for the control of the P-type impurity concentration in the surface portion of the semiconductor substrate 30 and thus promising more remarkable effects.

The implantation windows desirably have the dimension (Sₙ) that is fairly small. The P-type impurity concentration in the surface of the semiconductor substrate 30 can be adjusted according to, for example, the gap (Wₙ) between the implantation windows in the circumferential direction of the termination structure 32, the gap (Dₙ) between the implantation windows in the width direction of the termination structure 32, the ion implantation amount, and the conditions of thermal treatment.

### Fourth Embodiment

The P-type impurity region 2 of the termination structure 32, which is formed by a single ion implantation according to the first, second, and third embodiments, may be formed by the ion implantation performed more than once at different acceleration voltages.

FIG. 21 is a cross-sectional view showing a configuration of the termination structure 32 of the semiconductor device according to a fourth embodiment. According to the present embodiment, the P-type impurity region 2 including the low-concentration regions 2a and the high-concentration regions 2b and 2c is formed through: a first ion implantation for implanting a large dose amount of the P-type impurities at a low acceleration voltage using the implantation mask 20 having the aperture ratio that decreases toward the outer side of the termination structure 32; a second ion implantation for implanting a small dose amount of the P-type impurities at a high acceleration voltage using such implantation mask 20; and the subsequent thermal treatment.

According to the present embodiment, the dose amount in macroscopic view gradually decreases toward the outer side of the termination structure 32. As viewed microscopically, the regions having a large dose amount and the regions having a small dose amount are arranged alternately. Thus, the stable reverse withstand voltage is provided despite variations in the wafer processing as in the first embodiment.

The second ion implantation for implanting a low dose amount at a high acceleration voltage is performed, whereby the parts corresponding to the low-concentration regions 2a are formed before the thermal treatment. Consequently, the temperature or time required for the thermal treatment is reduced compared with that of the first embodiment, resulting in improved productivity.

The low-concentration regions 2a having a large depth can be formed through the second ion implantation. Therefore, the low-concentration regions 2a having the depth similar to that of the low-concentration regions 2a in the first, second, and third embodiment extend less in the transverse direction. This further facilitates the control of the impurity concentration profile of the P-type impurity region 2 in the width direction or in the circumferential direction of the termination structure 32, to thereby further increase the margin for variations in the wafer processing.

A plurality of the P-type impurity regions 2 having different impurity concentrations may be formed through the ion implantation performed more than once using individual implantation masks. Through the use of a mask of resist, the P-type impurity region 2 in part is formed by the ion implantation over the mask, so that the plurality of P-type impurity regions 2 having different impurity concentrations can be collectively formed. Alternatively, in part, the ion implantation is performed more than once using a plurality of implantation masks, to thereby form the plurality of P-type impurity regions having different impurity concentrations.

The formation of the P-type impurity region 2 of the termination structure 32 may be simultaneous with the ion implantation for forming the P-type impurity region in the active region inside of the termination structure 32 (the formation region of the IGBT 31). This simplifies the manufacturing process of the semiconductor device.

### Fifth Embodiment

A fifth embodiment refers to a modification of the configuration of the termination structure 32 according to the present invention.

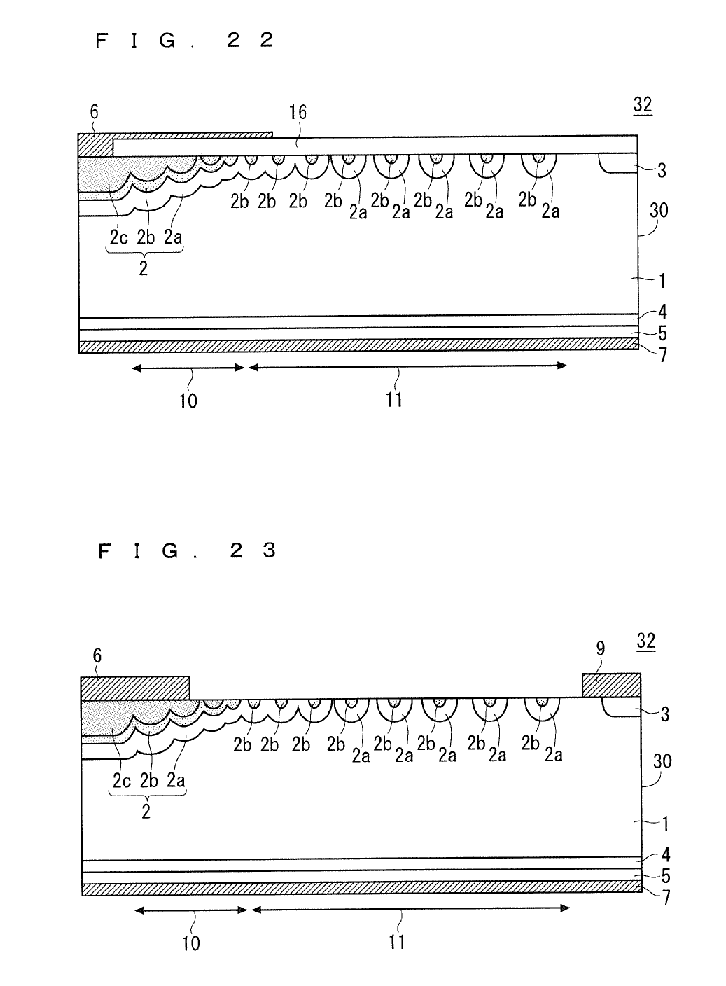

As shown in FIG. 22, for example, a part of the emitter electrode 6 extends over the termination structure 32 with a silicon oxide film 16 therebetween, whereby the emitter electrode 6 serves as a field plate. This can further suppress the electric field concentration in the termination structure 32. The emitter electrode 6 serving as the field plate is allowed to extend over the withstand voltage holding region 11 as shown in FIG. 22.

As shown in FIG. 23, a channel stopper electrode 9 connected to the N-type channel stopper region 3 may be formed over the outer periphery portion of the termination structure 32. The channel stopper electrode 9 works to suppress the expansion of the depletion layer in the width direction of the termination structure 32, and thus, is capable of preventing punch-through in a small area.

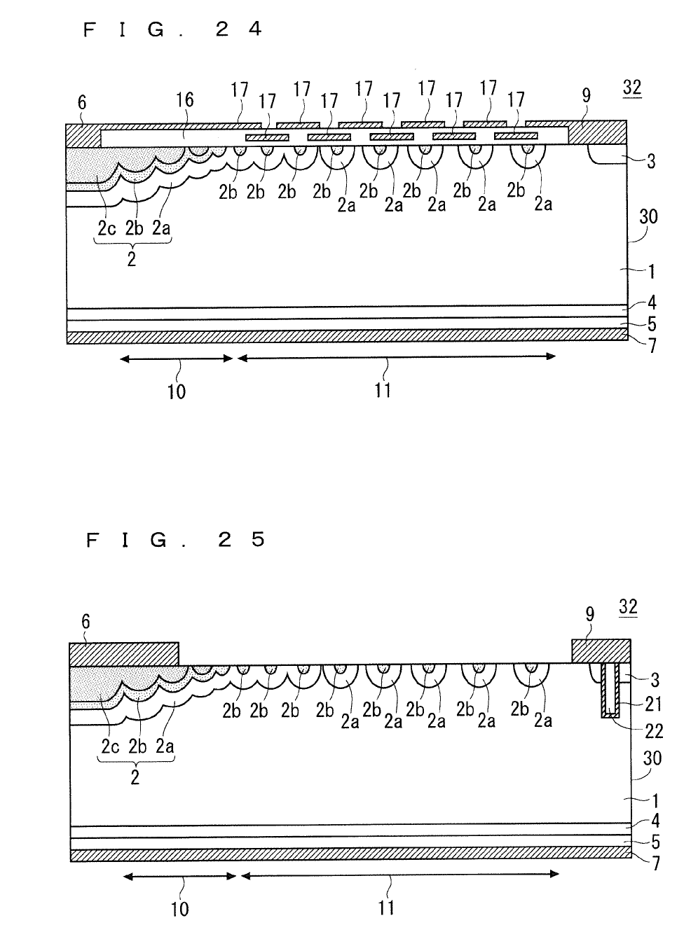

As shown in FIG. 24, a plurality of floating field plates 17 and the channel stopper 9 may be provided. The plurality of floating field plates 17 are located over the withstand voltage holding region 11 with the silicon oxide film 16 therebetween and are apart from the emitter electrode 6. The channel stopper 9 is formed over the outer periphery portion of the withstand voltage holding region 11 and is connected to the N-type channel stopper region 3 may be provided. The plurality of floating field plates 17 and the channel stopper electrode 9 are provided, thereby increasing the potential sharing rate in the withstand voltage holding region 11 and thus further suppressing the electric field concentration in the termination structure 32. Note that the N-type channel stopper region 3 may be omitted.

The present invention is applicable not only to the termination structures of IGBTs but also to the termination structures of semiconductor elements other than the IGBTs, such as diodes and MOS transistors.

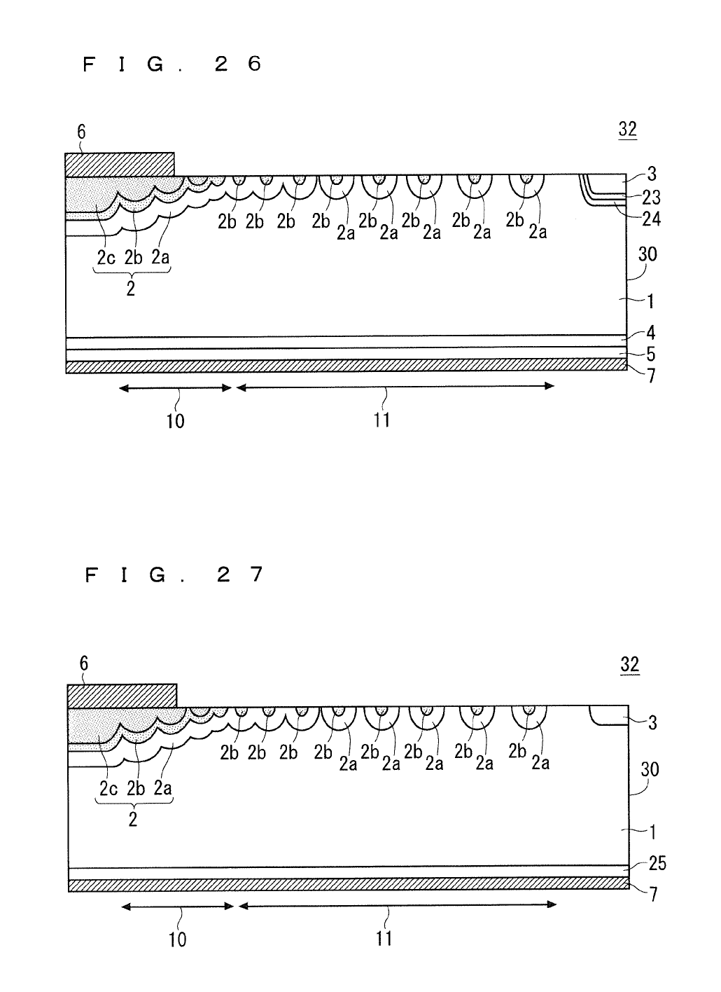

FIG. 25 shows an example of the present invention that is applied to the outer periphery structure of a trench-IGBT-type semiconductor element. A trench filling layer 22 that is an electric conductor electrically connected to the channel stopper electrode 9 and the insulating film 21 formed on the surface thereof are formed in the N-type channel stopper region 3. That is, the insulating layer 21 is located between the channel stopper electrode 9 and the trench filling layer 22. As shown in FIG. 25, the trench filling layer 22 penetrates the N-type channel stopper region 3 to project into the N-type drift region 1.

FIG. 26 shows an example of the present invention that is applied to the termination structure 32 of a semiconductor element including an N-type carrier storage layer. An N-type carrier storage layer 23 and a P-type impurity region 24 are formed to surround the N-type channel stopper region 3. That is, the P-type impurity region 24 is formed in the upper surface portion in the N-type drift region 1 of the termination structure 32, the N-type carrier storage layer 23 is formed in the upper surface portion in the P-type impurity region 24, and the N-type channel stopper region 3 is formed in the upper surface portion in the N-type carrier storage layer 23.

In a case where the present invention is applied to the termination structure of the trench-IGBT-31-type semiconductor element including the N-type carrier storage layer, the configuration shown in FIG. 26 may further include the channel stopper electrode 9, the insulating film 21, and the trench filling layer 21, which are shown in FIG. 25.

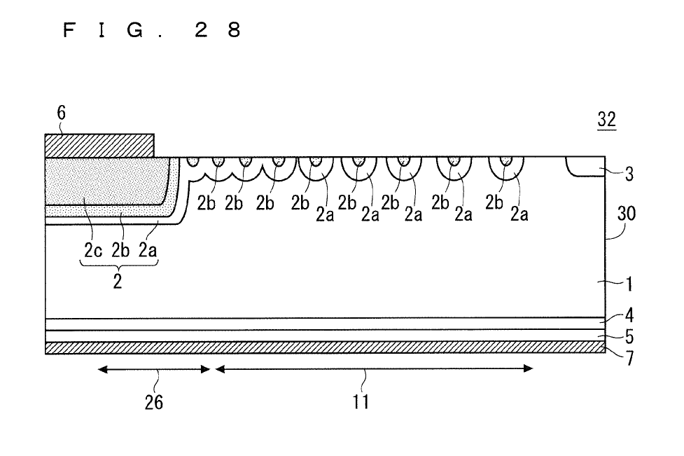

FIG. 27 shows an example of the present invention that is applied to the termination region of an element structure including a diode and an N-type MOSFET. In place of the N-type buffer region 4 and the P-type collector region 5 in the configuration shown in FIG. 2, an N-type drain (cathode) region 25 is formed in the lower surface portion of the semiconductor substrate 30.

According to the above description, the curvature relaxation region 10 is provided in the inner periphery portion of the termination structure 32. As shown in FIG. 28, the curvature relaxation region 10 may be omitted, and alternatively, the P-type impurity region 2 of the withstand voltage holding region 11 is connected to a P-type impurity region (p well) 26 in the outermost periphery of the semiconductor element. This configuration also allows the impurity concentration (the dose amount) in the P-type impurity region 2 of the withstand voltage holding region 11 in macroscopic view to gradually decrease toward the outer side of the termination structure 32. In addition, as viewed microscopically, the regions having a large dose amount and the regions having a small dose amount are arranged alternately. Moreover, the configuration includes the part in which the P-type impurity regions 2 are not connected to each other. Thus, the stable reverse withstand voltage is provided despite variations in the wafer processing as in the first embodiment.

With respect to the above-described dose amount of impurities in the ion implantation for forming the P-type impurity region 2, no allowance is made for factors including the influence of fixed charge and the dose drawn into the oxide film. Thus, the dose amount of impurities is desirably corrected with consideration given to such factors for the ion implantation in practice.

Although the semiconductor substrate 30 is formed of silicon according to the example described above, the present invention is also applicable to the semiconductor substrate formed of a wide band gap semiconductor substrate made of, for example, silicon carbide (SiC), gallium nitride (GaN) or diamond. Note that the optimal value of, for example, the dose amount is different from that of the semiconductor substrate 30 made of silicon.

In the present invention, the above embodiments can be arbitrarily combined, or each embodiment can be appropriately varied or omitted within the scope of the invention.

### EXPLANATION OF REFERENCE SIGNS

1 N-type drift region, 2 P-type impurity region, 2a low-concentration region, 2b high-concentration region, 2c high-concentration region, 3 N-type channel stopper region, 4 N-type buffer region, 5 P-type collector region, 6 emitter electrode, 7 collector electrode, 8 gate electrode, 9 channel stopper electrode, 10 curvature relaxation region, 11 withstand voltage holding region, 12 opening, 13 silicon oxide film, 16 silicon oxide film, 17 floating field plate, 20 implantation mask, 21 insulating film, 22 trench filling layer, 23 N-type carrier storage layer, 24 P-type impurity region, 25 N-type drain region, 26 P-type impurity region (p well), 30 semiconductor substrate, 31 IGBT, and 32 termination structure.

1. A semiconductor device comprising:
a semiconductor substrate including a semiconductor element formed therein; and
a termination structure located in an outer periphery portion of said semiconductor element in said semiconductor substrate, wherein
said termination structure includes:
a first impurity region of a first conductivity type located in said semiconductor substrate, and
a second impurity region of a second conductivity type located in an upper surface portion in said first impurity region, and
said second impurity region has, in macroscopic view, a second-conductivity-type impurity concentration that decreases from an inner periphery portion toward an outer periphery portion of said termination structure and has, in microscopic view, a part including second-conductivity-type regions separate from each other.

2. The semiconductor device according to claim 1, wherein said second impurity region includes a plurality of high-concentration regions of the second conductivity type and a low-concentration region of the second conductivity type surrounding each of said plurality of high-concentration regions.

3. The semiconductor device according to claim 2, wherein a gap between said plurality of high-concentration regions increases as closer to the outer periphery portion of said termination structure.

4. The semiconductor device according to claim 2, wherein said plurality of high-concentration regions have an impurity concentration that decreases as closer to the outer periphery portion of said termination structure.

5. The semiconductor device according to claim 2, wherein said plurality of high-concentration regions are arranged in a zigzag pattern.

6. The semiconductor device according to claim 1, wherein said second impurity region has a part in which the second-conductivity-type regions are separate from each other in a width direction of said termination structure.

7. The semiconductor device according to claim 1, wherein said second impurity region has a part in which the second-conductivity-type regions are separate from each other in a circumferential direction of said termination structure.

8. The semiconductor device according to claim 1, wherein said second impurity region has a part in which the second-conductivity-type regions are separate from each other both in a circumferential direction and in a width direction of said termination structure.

9. The semiconductor substrate according to claim 1, wherein
said semiconductor substrate is formed of silicon, and
said second impurity region has, in macroscopic view, an impurity concentration that is 1.0 E+12 cm⁻² to 2.0 E+12 cm⁻² in the inner periphery portion of said termination structure and decreases with a gradient of ⅓ to 1/20 toward the outer periphery portion of said termination structure.

10. The semiconductor device according to claim 1, wherein
said semiconductor substrate is formed of silicon, and
said second impurity region has, in macroscopic view, an impurity concentration that is 1.0 E+12 cm⁻² to 1.4 E+12 cm⁻² in the inner periphery portion of said termination structure and decreases with a gradient of ½ toward the outer periphery portion of said termination structure.

11. The semiconductor device according to claim 1, further comprising a second-conductivity-type region, said region being connected to an inner periphery portion of said second impurity region and having a higher impurity concentration or a greater depth than that of said second impurity region.

12. The semiconductor device according to claim 11, wherein the inner periphery portion of said second impurity region has an impurity concentration that gradually becomes higher or a depth that gradually becomes greater toward said second-conductivity-type region connected to the inner periphery portion of said second impurity region.

13. The semiconductor device according to claim 1, wherein an inner periphery portion of said second impurity region has an amount of change in impurity concentration, in macroscopic view, that gradually increases toward said second-conductivity-type region connected to the inner periphery portion of said second impurity region.

14. The semiconductor device according to claim 1, wherein said second impurity region has an amount of change in impurity concentration, in macroscopic view, that gradually increases from the inner periphery portion toward the outer periphery portion of said termination structure.

15. The semiconductor device according to claim 1, further comprising a field plate located over the inner periphery portion of said termination structure.

16. The semiconductor device according to claim 1, further comprising:
a channel stopper region of the first conductivity type located in the upper surface portion in said first impurity region of the outer periphery portion of said termination structure; and
a channel stopper electrode that is located over the outer periphery portion of said termination structure and is connected to said first impurity region.

17. The semiconductor device according to claim 1, further comprising at least one floating field plate located over the outer periphery portion of said termination structure.

18. A method for manufacturing semiconductor device, said method comprising the steps of:
(a) forming an implantation mask in a termination region surrounding a formation region of a semiconductor element in a semiconductor substrate, said implantation mask having a plurality of openings and having an aperture ratio that decreases from an inner periphery portion toward an outer periphery portion of said termination region;
(b) forming, as a termination structure, an impurity region in said termination region through an ion implantation of impurities using said implantation mask; and
(c) thermally diffusing said impurities implanted into said impurity region,
wherein said openings of said implantation mask have a dimension and a gap therebetween that are set to form, in said impurity region, adjacent parts connected to each other and adjacent parts that are unconnected by thermally diffusing impurities in said step (c).

19. The method for manufacturing semiconductor device according to claim 18, wherein
said implantation mask has said plurality of openings that are window-shaped,
said openings that are window-shaped have a gap therebetween, in a width direction of said termination region, that increases as closer to the outer periphery portion of said termination region, and
said openings that are window-shaped have a fixed gap therebetween in a circumferential direction of said termination region.

20. The method for manufacturing semiconductor device according to claim 18, wherein
said implantation mask has said plurality of openings that are window-shaped,
said openings that are window-shaped have a fixed gap therebetween in a width direction of said termination region, and
said openings that are window-shaped have a gap therebetween, in a circumferential direction of said termination region, that increases as closer to the outer periphery portion of said termination region.

21. The method for manufacturing semiconductor device according to claim 18, wherein
said implantation mask has said plurality of openings that are window-shaped, and
said openings that are window-shaped have gaps therebetween, in a width direction of said termination region and in a circumferential direction of said termination region, that increase as closer to the outer periphery portion of said termination region.

22. The method for manufacturing semiconductor device according to claim 18, wherein
said implantation mask has said plurality of openings that are window-shaped, and
said openings that are window-shaped have a dimension that decreases as closer to the outer periphery portion of said termination region.

23. The method for manufacturing semiconductor device according to claim 19, wherein said openings that are window-shaped are arranged in a zigzag pattern.

24. The method for manufacturing semiconductor device according to claim 18, wherein said step (b) is performed more than once at different acceleration voltages for said ion implantation.

25. The method for manufacturing semiconductor device according to claim 18, wherein said steps (a) and (b) are performed more than once using different patterns of said implantation mask.
